(19) United States
(12) Patent Application Publication
(10) Pub. No.: US 2014/0374853 A1
(43) Pub. Date: Dec. 25, 2014

(54) COMPONENT INCLUDING MEANS FOR REDUCING ASSEMBLY-RELATED MECHANICAL STRESSES AND METHODS FOR MANUFACTURING SAME

(71) Applicants: Heribert WEBER, Nuertingen (DE); Hartmut KUEPPERS, Reutlingen (DE); Jens FREY, Filderstadt (DE); Jochen REINMUTH, Reutlingen (DE); Neil DAVIES, Sonnenbuehl-Genkingen (DE)

(72) Inventors: Heribert WEBER, Nuertingen (DE); Hartmut KUEPPERS, Reutlingen (DE); Jens FREY, Filderstadt (DE); Jochen REINMUTH, Reutlingen (DE); Neil DAVIES, Sonnenbuehl-Genkingen (DE)

(73) Assignee: Robert Bosch GmbH, Stuttgart (DE)

(21) Appl. No.: 14/307,662

(22) Filed: Jun. 18, 2014

(30) Foreign Application Priority Data
Jun. 19, 2013 (DE) 10 2013 211 555.5

(51) Int. Cl. B81C 1/00; B81B 3/00

(52) U.S. Cl. CPC B81C 1/00825; B81B 3/0072; B81C 2201/05
USPC 257/415; 438/51

(57) ABSTRACT

Measures are provided for stress decoupling between a semiconductor component and its mounting support, these measures being implementable very easily, inexpensively and in a space-saving manner, regardless of the substrate thickness of the component, and not being limited to soldered connections but instead also being usable in conjunction with other mounting and joining techniques. These measures relate to components, which include at least one electrical and/or micromechanical functionality and at least one wiring level, which is formed in a layer structure on a main surface of the component substrate, at least one mounting surface being implemented in the wiring level to establish a mechanical and/or electrical connection of the component to a support. The at least one mounting surface is spring mounted and is separated from the layer structure in at least some areas for this purpose.

### RELATED APPLICATION INFORMATION

The present application claims priority to and the benefit of German patent application no. 10 2013 211 555.5, which was filed in Germany on Jun. 19, 2013, the disclosure of which is incorporated herein by reference.

### FIELD OF THE INVENTION

The present invention relates in general to a component including an arrangement for reducing assembly-related mechanical stresses. The component includes at least one electrical and/or micromechanical functionality and a wiring level, which is formed in a layer structure on a main surface of the component substrate, at least one mounting surface being implemented in the wiring level for establishing a mechanical and/or electrical connection of the component to a support.

### BACKGROUND INFORMATION

The layer structure having the at least one mounting surface in the wiring level may fundamentally also be situated on the same side of the component as the electrical and/or micromechanical functionality. In one specific embodiment of the present invention, however, the at least one electrical and/or micromechanical functionality is implemented in a layer structure on the front side of a semiconductor substrate, while the wiring level having the at least one mounting surface is formed in a layer structure on the rear side of the semiconductor substrate. In this case, at least one through-contact is provided, which establishes an electrical connection between the functionality in the front-side layer structure and the wiring level in the rear-side layer structure.

In addition, the present invention also relates to a method for manufacturing such components.

The micromechanical and electrical functionality of semiconductor components is influenced and, in the event of an uncontrolled occurrence, also affected negatively by mechanical stresses in the structure or in the layer structure of the component. Such mechanical stresses are often assembly-related, in particular when the component and the support have different thermal expansion coefficients. When the semiconductor substrate of the component is thinner, the effects on its electrical or micromechanical functionality are greater. Therefore, with small and thin silicon-based MEMS components, interference signals frequently occur in practice, which are attributable to an assembly-related bending of the component structure and have a definite negative effect on the function of the MEMS component.

There is thus one possibility of stress decoupling between the electrical or micromechanical functionality implemented in the layer structure of a component and a mounting support by using components having a relatively thick semiconductor substrate.

It is believed to be discussed in US 2007/0085220 that the mechanical and, if necessary, also electrical connections between a semiconductor component and its mounting support are strained in particular due to thermally induced mechanical stresses in the structure. In the case of soldered connections, these mechanical stresses may even result in breakage of individual connection points. Mechanical stresses in the area of soldered connections between the component and the mounting support should be dissipated with the aid of the measures described in US 2007/0085220 with the goal of improving the reliability of such soldered connections. It is therefore provided that the mounting surfaces of the component be equipped with spring elements which protrude away from the surface of the component. These spring elements are then tied into the soldered connection between the component and the mounting support and should thus absorb the mechanical stresses occurring in this area.

The measures discussed in US 2007/0085220 are applicable exclusively to soldered connections. Furthermore, the implementation of spring elements, which are placed on the component surface so that they protrude away from the mounting surfaces, is relatively complex with regard to the process technology. Furthermore, the spring elements are reinforced by embedding them in the soldering material, which greatly restricts their elasticity. The stress decoupling effect of such spring elements is limited accordingly.

### SUMMARY OF THE INVENTION

Measures for stress decoupling between a semiconductor component and its mounting support are provided with the present invention; these measures may be implemented very easily, inexpensively and in a space-saving manner, regardless of the substrate thickness of the component, and they are not limited to soldered connections but instead may also be used in conjunction with other mounting and joining techniques.

Stress decoupling is achieved according to the present invention by the fact that the at least one mounting surface of the component itself is spring mounted and is therefore separated from the layer structure on the rear side in at least some areas.

It is thus provided according to the present invention that a cantilevered and resilient stress decoupling structure be implemented in the wiring level of the mounting surface. The mode of action of such a stress decoupling structure depends essentially only on the layout of the wiring level and of the directly adjacent layers of the layer structure, which determine the integration of the mounting surface into the layer structure. The elastic properties of the stress decoupling structure may therefore be very readily influenced and predefined. Furthermore, only standard methods of semiconductor processing are required for manufacturing such a stress decoupling structure and these methods are readily integratable into the fabrication of a semiconductor component of the type in question here.

Regarding the layout of the wiring level and the directly adjacent layers, it may be predefined in particular whether the spring-mounted mounting surface is to be deflectable essentially within the wiring level and/or perpendicularly to the wiring level.

In one specific embodiment of the present invention, the mounting surface is integrated into the layer structure via a spring suspension, which is implemented together with the mounting surface in the wiring level. In this case, the spring action may be varied in a highly differentiated manner through the number, arrangement, thickness, width and shape of the spring elements.

If the mounting surface also functions as a terminal pad for electrical contacting of the component, then it often proves reasonable to provide at least one dielectric layer through which the spring-mounted mounting surface and the semiconductor substrate are electrically insulated with respect to one another.

As already discussed above, there are various possibilities for embodying and refining the teaching of the present invention in an advantageous manner. For this purpose, reference is made, on the one hand, to the patent claims, which are subordinate to the independent patent claims, and, on the other hand, to the following description of several exemplary embodiments of the present invention with reference to the figures.

### BRIEF DESCRIPTION OF THE DRAWINGS

FIG. 1 shows a schematic sectional representation of a vertically integrated hybrid MEMS assembly 100 including a MEMS component 110 and an ASIC component 120, MEMS component 110 being mounted face down on ASIC component 120, and ASIC component 120 being equipped with a stress decoupling structure according to the present invention for mounting on a component support.

FIGS. 2a, 2b, 2c, and 2d illustrate one variant of the method according to the present invention for manufacturing a component including such a stress decoupling structure on the basis of schematic sectional representations through the component substrate during manufacture.

FIGS. 3a, 3b, and 3c illustrate another variant of the method according to the present invention on the basis of schematic sectional representations through a component substrate.

### DETAILED DESCRIPTION

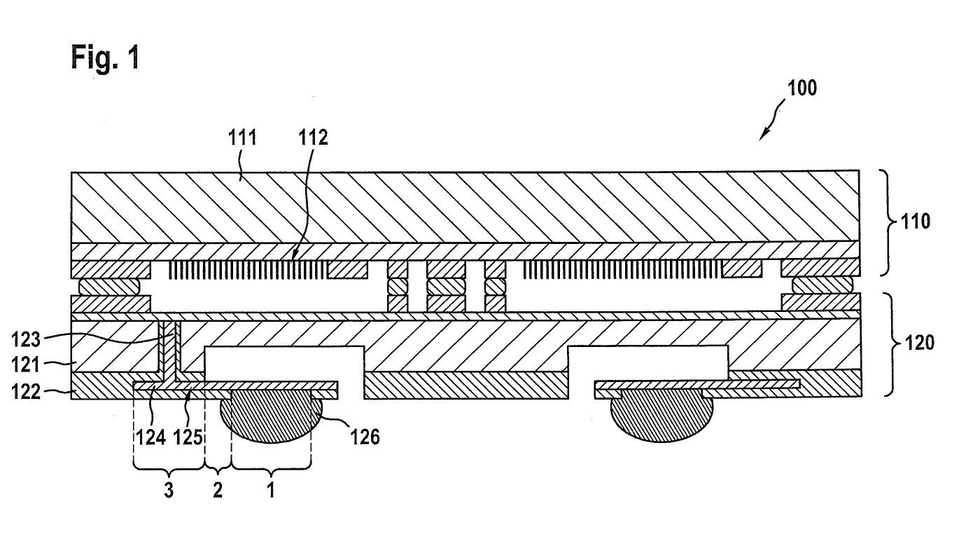

As already mentioned, assembly 100 illustrated in FIG. 1 is a vertically integrated hybrid assembly having a MEMS function, which is implemented in a MEMS component 110, and circuit functions, which are implemented in a separate ASIC component 120. The MEMS function here is to detect accelerations with the aid of a sensor structure 112, which is implemented in a layer structure on MEMS substrate 111. The sensor signals are analyzed with the aid of the circuit functions configured in the front side of ASIC component 120, but not shown in detail here. Sensor structure 112 is capped here practically by ASIC component 120 since MEMS component 110 is mounted face down on the front side of ASIC component 120.

Assembly 100 is configured for ASIC-side mounting on a support (not shown here), such as a printed circuit board, for example. Since electrical contacting of assembly 100 also takes place via the rear side of ASIC component 120, through-contacts 123, which electrically connect the circuit functions in the front side of ASIC component 120 to a wiring level 124, are formed in ASIC component 120. Wiring level 124 is implemented in a rear-side layer structure 122 on the ASIC substrate 121. Mounting surfaces 125 in the form of terminal pads are formed in this wiring level 124. According to the present invention, these terminal pads 125 are spring-mounted in that they are separated from layer structure 122 in at least some areas.

In the exemplary embodiment shown here, the mounting and electrical contacting of assembly 100 take place with the aid of solder balls 126. An area 1 of wiring level 124 or of mounting surface 125 is furnished for this purpose with good wetting properties for soldering, whereas poor wetting for soldering is ensured in an annular area 2 around area 1. This may be achieved either by using two metals of different wetting properties for both areas 1 and 2 of the wiring level 124 or by applying a wetting layer or a nonwetting layer. An Al layer in particular is suitable as a nonwetting layer, while Au, Ag or Ni layers may be considered as wetting layers.

Both areas 1 and 2 here are completely undercut, while the mounting surface in adjacent area 3 is integrated into rear-side layer structure 122. These areas 1 and 2 together with soldered connection 126 are therefore movable with respect to the assembly structure and thus contribute to stress decoupling between an assembly support and the MEMS and ASIC functions of assembly 100.

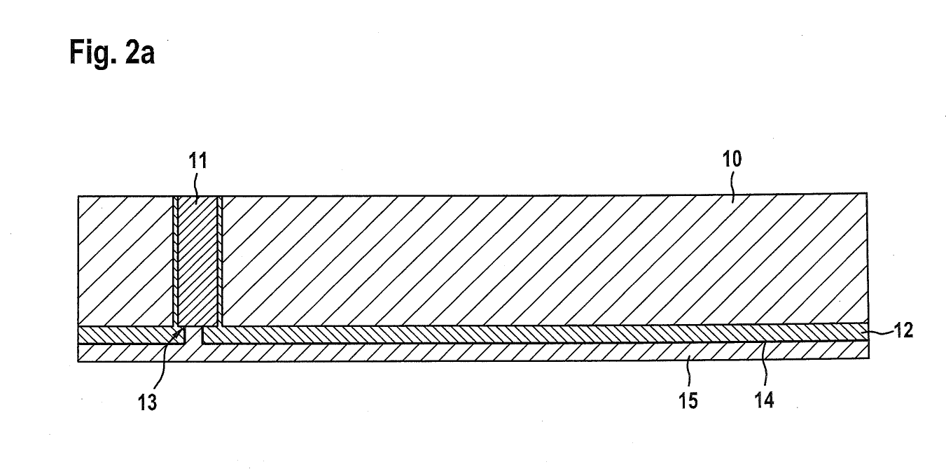

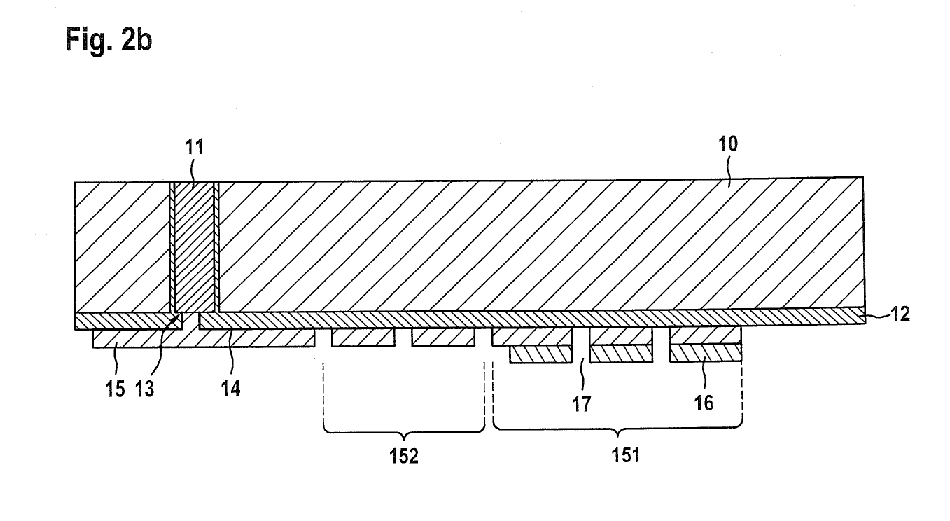

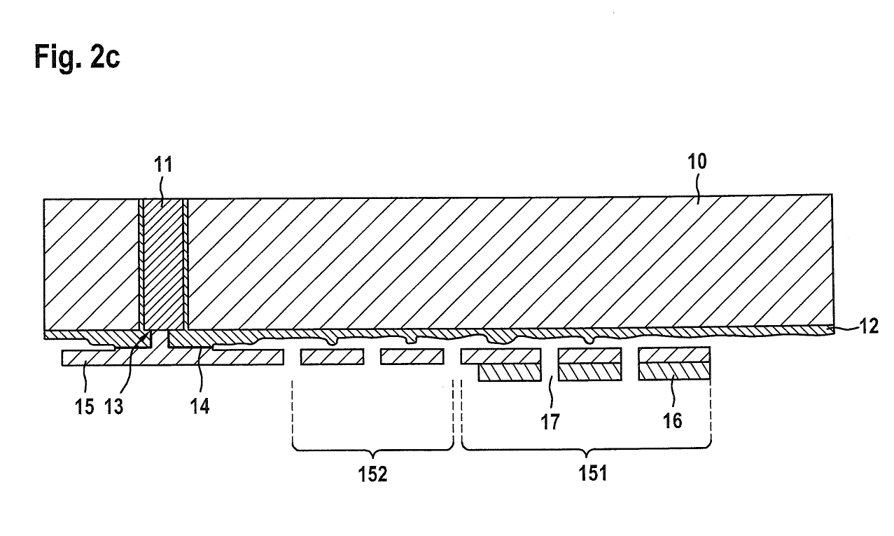

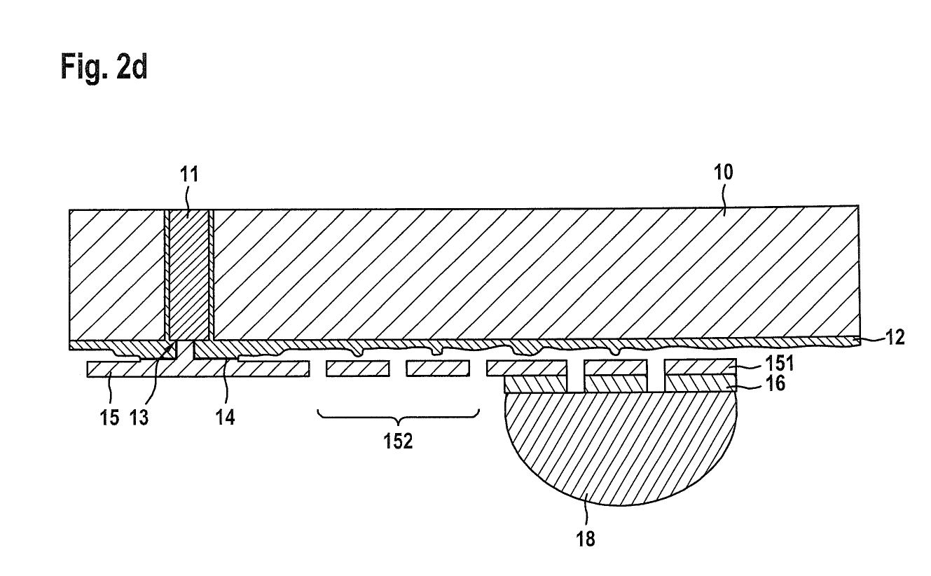

One variant of the method according to the present invention for creating such a stress decoupling structure is described below in conjunction with FIGS. 2a through 2d on the example of a semiconductor component whose functionality is implemented in a layer structure on the front side of component substrate 10, as in the case of ASIC component 120 shown in FIG. 1. This functionality is not shown in detail in FIGS. 2a through 2d since it does not play any role in the manufacture of the rear-side stress decoupling structure. A through-contact 11, which establishes an electrical connection between the functionality on the front side of the substrate and on the rear side of the substrate, is formed in component substrate 10. A layer structure having at least one wiring level is then created on the rear side of component substrate 10. Therefore, a dielectric layer 12 is applied initially to the rear side of the substrate in the exemplary embodiment described here. This may be a CVD-TEOS oxide, for example. Dielectric layer 12 is opened in the area of through-contact 11 to create a contact area 13. FIG. 2a shows component substrate 10 after deposition of a TiN sacrificial layer 14 and then an Al layer 15 over dielectric layer 12 structured in this way. TiN sacrificial layer 14 functions as a barrier and as an adhesive layer for Al layer 15 at the same time.

Al layer 15 is then configured as a wiring level. A wetting layer 16 of Ni or NiAu, for example, is therefore deposited initially on Al layer 15 and structured. Al layer 15 is next structured together with wetting layer 16 to form conductors, a mounting surface 151 and a spring structure 152 via which mounting surface 151 is integrated into wiring level 15. Perforation openings 17 are also formed in the area of mounting surface 151 and should facilitate an undercut of mounting surface 151. Perforation openings 17 are configured to be so small that the soldering material does not penetrate into perforation openings 17 but instead spreads over them. The result of this structuring process is shown in FIG. 2b.

Mounting surface 151 is now separated from the rear-side layer structure in at least some areas according to the present invention. For this purpose, mounting surface 151 is undercut, whereby TiN sacrificial layer 14 beneath mounting surface 151 and spring structure 152 is initially removed. Dielectric layer 12 is then also attacked but not removed completely. FIG. 2c illustrates that, even after exposing mounting surface 151 and spring structure 152, component substrate 10 is still insulated electrically by dielectric layer 12 from mounting surface 151 and spring structure 152. Although only a comparatively small distance between mounting surface 151 and component substrate 10 is created due to the very thin sacrificial layer 14 in this process variant, short-circuits between mounting surface 151 and component substrate 10 may thus be reliably prevented. Due to this small distance, the variant described here is suitable in particular for applications in which stress decoupling takes place primarily in parallel with the component substrate.

Finally, for mounting on a support, soldering material 18 in the form of paste or solder balls is also applied and melted. In the process, a solder ball 18 is formed in the area provided with wetting layer 16, as illustrated in FIG. 2d.

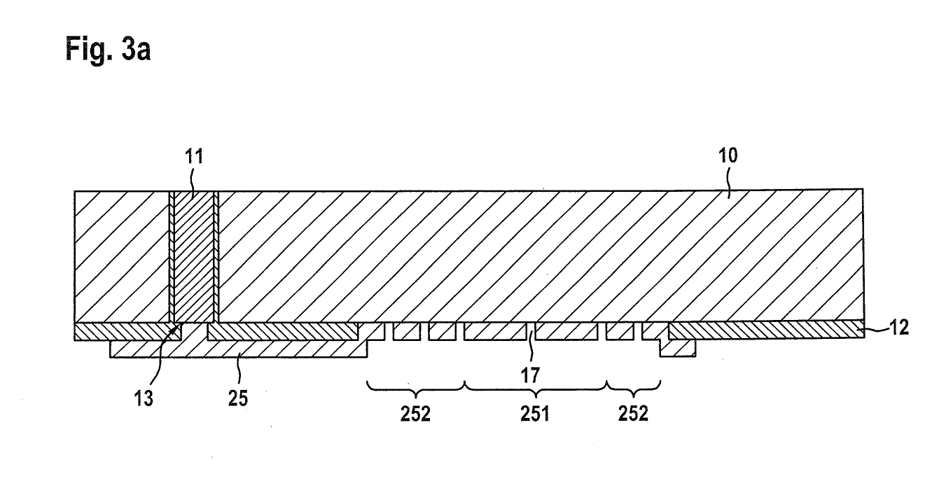

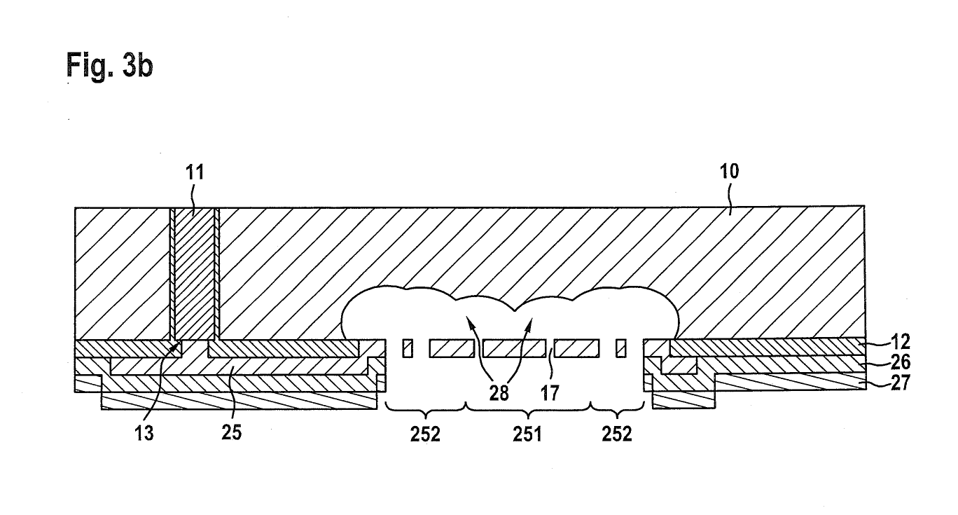

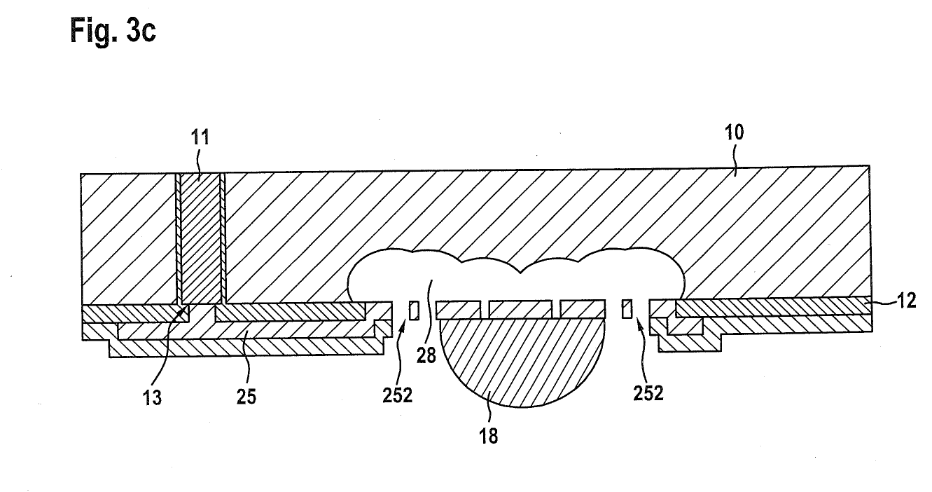

In conjunction with FIGS. 3a through 3c, a process variant for implementation of stress decoupling structures will now be described, which permits stress decoupling in parallel and also perpendicularly to the component substrate. This process variant is derived from a component substrate 10, as has already been described in conjunction with FIGS. 2a through 2d.

Again in this case, a layer structure having a wiring level is created on the rear side of component substrate 10, a dielectric layer 12 being initially applied to the rear side of the substrate for this purpose. This dielectric layer 12 is then structured. On the one hand, a contact area 13 to through-contact 11 is thereby created. On the other hand, dielectric layer 12 is opened in the undercut area toward the mounting surface and spring structure. FIG. 3a shows component substrate 10 after a metal layer 25 has been deposited over the thus structured dielectric layer 12 and has been structured as a wiring level. In the exemplary embodiment described here, wiring level 25 is implemented in the form of a Cu layer, which has a good wetting property for soldering.

A passivation layer 26, such as an SiN layer, for example, having a poor wetting for soldering is deposited over this. This passivation layer 26 is opened in the area of mounting surface 251 in a structuring process. Masking 27 used for this purpose may also be used for the subsequent etching process to expose mounting surface 251 and spring structure 252. The result of this etching process is shown in FIG. 3b, where a cavern 28 has been created in component substrate 10 beneath mounting surface 251. Since in this process variant, component substrate 10 functions as a sacrificial layer, greater distances between component substrate 10 and spring-mounted mounting surface 251 may also be implemented here. An insulation layer for preventing short-circuits is then not absolutely necessary. In this case, mounting surface 251 is advantageously integrated into the layer structure on the rear side of the substrate on more than one side to achieve a stable integration of the component and to prevent undefined vibrations of the component on the printed board. In this context, it has also proven advantageous if wiring level 25 is additionally under tensile strain.

Finally, here again, soldering material 18 in the form of a paste or solder balls is applied to a support for the mounting and melted there. In the process, a solder ball 18 is formed on mounting surface 251. FIG. 3c shows component substrate 10 with solder ball 18 after removal of masking 27 on the rear side.

In conclusion, it should also be pointed out that the wiring level including the mounting surface may also be formed on the front side of a component and/or in a layer structure, which also includes other wiring levels insulated from one another by dielectric layers.

What is claimed is:

1. A component, comprising:
an arrangement for reducing assembly-related mechanical stresses, at least including:
an electrical and/or micromechanical functionality, and
a wiring level, which is formed in a layer structure on a main surface of the component substrate, at least one mounting surface for establishing a mechanical and/or electrical connection of the component to a support being implemented in the wiring level, wherein the at least one mounting surface is spring mounted and separated from the layer structure in at least some areas.

2. The component of claim 1, wherein the at least one electrical and/or micromechanical functionality is implemented in a layer structure on a semiconductor substrate, wherein the wiring level having the at least one mounting surface is formed in a layer structure on the rear side of the semiconductor substrate, and wherein at least one through-contact is provided, which establishes an electrical connection between the functionality in the front-side layer structure and the wiring level in the rear-side layer structure.

3. The component of claim 1, wherein the spring-mounted mounting surface is deflectable essentially within the wiring level and/or perpendicularly to the wiring level.

4. The component of claim 1, wherein the mounting surface is integrated into the rear-side layer structure via a spring suspension, and wherein the spring suspension together with the mounting surface is formed in the wiring level.

5. The component of claim 1, wherein the spring-mounted mounting surface and the semiconductor substrate are electrically insulated from one another by at least one dielectric layer.

6. A method for manufacturing a component, the method comprising:
providing an arrangement for reducing assembly-related mechanical stresses with an electrical and/or micromechanical functionality; and
forming in the arrangement a wiring level, in a layer structure on a main surface of a component substrate, at least one mounting surface for establishing a mechanical and/or electrical connection of the component to a support being implemented in the wiring level;
wherein the mounting surface is separated from the layer structure in at least some areas, in that the corresponding wiring level is undercut in the area of the mounting surface.

7. The method of claim 6, wherein a spring suspension for the mounting surface is implemented in the wiring level of the mounting surface, and wherein the spring suspension together with the mounting surface is separated from the layer structure.

8. The method of claim 6, wherein the wiring level of the mounting surface is created over at least one sacrificial layer of the layer structure, and this sacrificial layer is removed at least partially during undercutting of the mounting surface.

9. The method of claim 6, wherein a cavern is created in the rear side of the semiconductor substrate during undercutting of the mounting surface.

10. The method of claim 6, wherein perforation openings for undercutting of the mounting surface are created in the area of the mounting surface during the structuring of the wiring level.

11. The method of claim 7, wherein the mounting surface and the spring suspension of the mounting surface are formed from different materials and/or are coated with different materials, so that the mounting surface has definitely better wetting properties for soldering than the spring suspension.
